(19) United States
(12) Patent Application Publication
(10) Pub. No.: US 2025/0183924 A1
(43) Pub. Date: Jun. 5, 2025

(54) RADIO FREQUENCY MODULE

(71) Applicant: Murata Manufacturing Co., Ltd., Kyoto (JP)

(72) Inventors: Satoshi SAKITA, Kyoto (JP); Wataru TAKAHASHI, Kyoto (JP); Naofumi TAKEZONO, Kyoto (JP); Katsuya IKEGAMI, Kyoto (JP)

(21) Appl. No.: 18/956,808

(22) Filed: Nov. 22, 2024

(30) Foreign Application Priority Data
Dec. 4, 2023 (JP) 2023-204916

(51) Int. Cl. H04B 1/00; H03F 3/24; H04B 1/04

(52) U.S. Cl. CPC H04B 1/0064; H03F 3/245; H04B 1/04; H03F 2200/165; H03F 2200/171; H03F 2200/451

(57) ABSTRACT

A radio frequency module includes a first semiconductor device that includes a circuit for a signal in a first frequency band, a second semiconductor device that includes a circuit for a signal in a second frequency band, a first external connection terminal that receives a transmit signal in the first frequency band, a second external connection terminal that receives a transmit signal in the second frequency band, a first switch that is electrically connected to the first external connection terminal or the second external connection terminal, a power amplifier that receives a signal outputted from the first switch, a third external connection terminal that receives a selectively-transported output signal from the power amplifier and that is electrically connected to an external first antenna, and a fourth external connection terminal that receives a selectively-transported output signal from the power amplifier and that is electrically connected to an external second antenna.

### CROSS REFERENCE TO RELATED APPLICATION

This application claims priority from Japanese Patent Application No. 2023-204916 filed on Dec. 4, 2023. The content of this application is incorporated herein by reference in its entirety.

### BACKGROUND ART

The present disclosure relates to a radio frequency module.

FIG. 1 in Japanese Unexamined Patent Application Publication (Translation of PCT Application) No. 2007-512781 illustrates a wireless mobile unit including an ultra wide band (UWB) module and a code division multiple access (CDMA) module.

### BRIEF SUMMARY

The wireless mobile unit described in Japanese Unexamined Patent Application Publication (Translation of PCT Application) No. 2007-512781, which has the two modules, is large in size and high in cost.

The present disclosure reduces size and cost of a radio frequency module.

A radio frequency module according to an aspect of the present disclosure includes a first semiconductor device, a second semiconductor device, a first external connection terminal, a second external connection terminal, a first switch, a power amplifier, a third external connection terminal, and a fourth external connection terminal. The first semiconductor device includes a circuit for a signal in a first frequency band. The second semiconductor device includes a circuit for a signal in a second frequency band different from the first frequency band. The first external connection terminal receives a transmit signal in the first frequency band. The second external connection terminal receives a transmit signal in the second frequency band. The first switch is electrically connected selectively to the first external connection terminal or the second external connection terminal. The power amplifier receives a signal outputted from the first switch. The third external connection terminal receives a selectively-transported output signal from the power amplifier, and is electrically connected to an external first antenna. The fourth external connection terminal receives a selectively-transported output signal from the power amplifier, and is electrically connected to an external second antenna.

A radio frequency module according to an aspect of the present disclosure includes a first semiconductor device, a second semiconductor device, a first external connection terminal, a second external connection terminal, a first switch, a power amplifier, a second switch, a diplexer, and a fifth external connection terminal. The first semiconductor device includes a circuit for a signal in a first frequency band. The second semiconductor device includes a circuit for a signal in a second frequency band different from the first frequency band. The first external connection terminal receives a transmit signal in the first frequency band. The second external connection terminal receives a transmit signal in the second frequency band. The first switch is electrically connected selectively to the first external connection terminal or the second external connection terminal. The power amplifier receives a signal outputted from the first switch. The second switch receives an output signal from the power amplifier. The diplexer receives a signal outputted from the second switch. The fifth external connection terminal receives a signal outputted from the diplexer, and is electrically connected to an external third antenna.

The present disclosure achieves a reduction in size and cost of a radio frequency module.

### BRIEF DESCRIPTION OF THE DRAWINGS

FIG. 1 is a diagram illustrating the configuration of a radio frequency module of a first comparison example;

FIG. 2 is a diagram illustrating the configuration of a radio frequency module of a first configuration example of a first embodiment;

FIG. 3 is a timing chart of an operational timing example of the first embodiment and a second embodiment;

FIG. 4 is a diagram illustrating the configuration of a radio frequency module of a second configuration example of the first embodiment;

FIG. 5 is a diagram illustrating the configuration of a radio frequency module of a third configuration example of the first embodiment;

FIG. 6 is a diagram illustrating the configuration of a radio frequency module of a fourth configuration example of the first embodiment;

FIG. 7 is a diagram illustrating the configuration of a radio frequency module of a fifth configuration example of the first embodiment;

FIG. 8 is a diagram illustrating the configuration of a radio frequency module of a sixth configuration example of the first embodiment;

FIG. 9 is a diagram illustrating the configuration of a radio frequency module of a second comparison example;

FIG. 10 is a diagram illustrating the configuration of a radio frequency module of a first configuration example of the second embodiment; and

FIG. 11 is a diagram illustrating the configuration of a radio frequency module of a second configuration example of the second embodiment.

### DETAILED DESCRIPTION

Embodiments of the present disclosure will be described in detail below on the basis of the drawings. The present disclosure is not limited by the embodiments. Needless to say, the embodiments are exemplary, and partial replacement or combination of configurations described in different embodiments may be made. In a second embodiment and its subsequent embodiments, points common to those in a first embodiment will not be described, and only different points will be described. In particular, substantially the same operational effect caused by substantially the same configuration will not be described in the second embodiment and its subsequent embodiments.

### First Embodiment

To understand the first embodiment easily, a first comparison example will be described prior to description about the first embodiment.

### The Configuration of the First Comparison Example

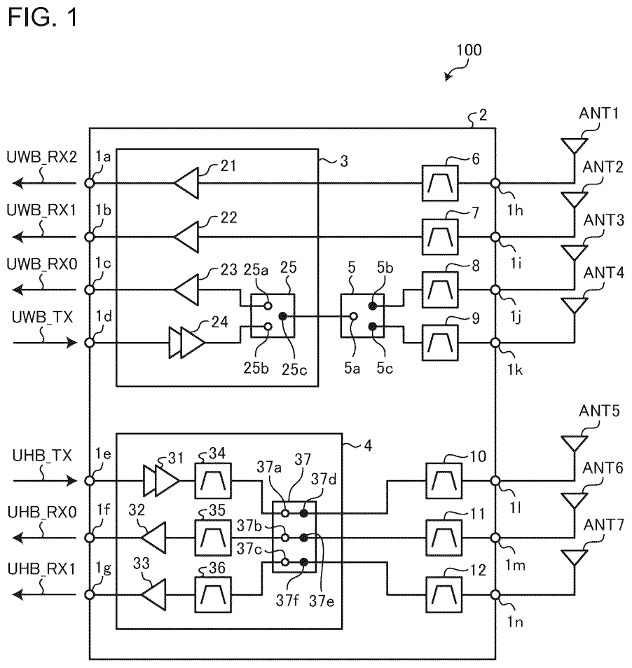

FIG. 1 is a diagram illustrating the configuration of a radio frequency module of the first comparison example.

A radio frequency module 100 includes a substrate 2, an ultra wide band (UWB) circuit 3, an ultra high band (UHB) circuit 4, a switch 5, and bandpass filters 6 to 12. The UWB circuit 3, the UHB circuit 4, the switch 5, and the bandpass filters 6 to 12 are mounted on/in the substrate 2.

The switch 5 and the bandpass filters 6 to 9 may be included in the UWB circuit 3. The bandpass filters 10 to 12 may be included in the UHB circuit 4.

UWB, which is defined, for example, in IEEE 802.15.4z, has a frequency band, for example, of the order from 6 GHz to 8 GHz. However, the present disclosure is not limited to this. UHB, which is, for example, n77, n78, or n79 of the 5th Generation New Radio (5GNR), has a frequency band, for example, of the order from 3.3 GHz to 5 GHz. However, the present disclosure is not limited to this.

The UWB circuit 3 is, for example, a single semiconductor device formed on/in a Si (silicon) substrate. However, the present disclosure is not limited to this. The UHB circuit 4 is, for example, a single semiconductor device formed on/in a GaAs (gallium arsenide) substrate. However, the present disclosure is not limited to this. For example, only a power amplifier 24 (described below) of the UWB circuit 3 may be included in a semiconductor device on/in a Si substrate, or only a power amplifier 31 (described below) of the UHB circuit 4 may be included in a semiconductor device on/in a GaAs substrate.

The UWB circuit 3 corresponds to an exemplary “first semiconductor device” of the present disclosure. The UHB circuit 4 corresponds to an exemplary “second semiconductor device” of the present disclosure.

“Second semiconductor device” is assumed to be the UHB circuit 4. However, the present disclosure is not limited to this. “Second semiconductor device” may be, for example, a middle high band (MHB) circuit. MHB, which is, for example, Band 39 or Band 41 of long-term evolution (LTE), has a frequency band, for example, of the order from 1.8 GHz to 2.7 GHz. The frequency band of signals inputted/outputted by “second semiconductor device” is, for example, lower than that of signals inputted/outputted by “first semiconductor device”.

The substrate 2 has terminals 1a to 1n.

A UWB receive signal UWB_RX2 is outputted from the terminal 1a. A UWB receive signal UWB_RX1 is outputted from the terminal 1b. A UWB receive signal UWB_RX0 is outputted from the terminal 1c. A UWB transmit signal UWB_TX is inputted to the terminal 1d.

A UHB transmit signal UHB_TX is inputted to the terminal 1e. A UHB receive signal UHB_RX0 is outputted from the terminal 1f. A UHB receive signal UHB_RX1 is outputted from the terminal 1g.

The terminal 1h is electrically connected to an antenna ANT1. The terminal 1i is electrically connected to an antenna ANT2. The terminal 1j is electrically connected to an antenna ANT3. The terminal 1k is electrically connected to an antenna ANT4. The terminal 1l is electrically connected to an antenna ANT5. The terminal 1m is electrically connected to an antenna ANT6. The terminal in is electrically connected to an antenna ANT7.

The terminal 1d corresponds to an exemplary “first external connection terminal” of the present disclosure. The terminal 1e corresponds to an exemplary “second external connection terminal” of the present disclosure. The terminal 1j or 1k corresponds to an exemplary “third external connection terminal” of the present disclosure. The terminal 1l corresponds to an exemplary “fourth external connection terminal” of the present disclosure. The antenna ANT3 or ANT4 corresponds to an exemplary “first antenna” of the present disclosure. The antenna ANT5 corresponds to an exemplary “second antenna” of the present disclosure.

The UWB circuit 3 includes low-noise amplifiers 21 to 23, the power amplifier 24, and a switch 25.

The low-noise amplifier 21 is electrically connected, at its output terminal, to the terminal 1a. The low-noise amplifier 21 is electrically connected, at its input terminal, to a first end of the bandpass filter 6. The bandpass filter 6 is electrically connected, at its second end, to the terminal 1h.

The low-noise amplifier 21 amplifies a signal, which has been received at the antenna ANT1 and which has been band-passed by the bandpass filter 6, and outputs the UWB receive signal UWB_RX2 to the terminal 1a.

The low-noise amplifier 22 is electrically connected, at its output terminal, to the terminal 1b. The low-noise amplifier 22 is electrically connected, at its input terminal, to a first end of the bandpass filter 7. The bandpass filter 7 is electrically connected, at its second end, to the terminal 1i.

The low-noise amplifier 22 amplifies a signal, which has been received at the antenna ANT2 and which has been band-passed by the bandpass filter 7, and outputs the UWB receive signal UWB_RX1 to the terminal 1b.

The low-noise amplifier 23 is electrically connected, at its output terminal, to the terminal 1c. The low-noise amplifier 23 is electrically connected, at its input terminal, to a terminal 25a of the switch 25.

The power amplifier 24 is electrically connected, at its input terminal, to the terminal 1d. The power amplifier 24 is electrically connected, at its output terminal, to a terminal 25b of the switch 25.

The switch 25 electrically connects selectively between the terminal 25a and a terminal 25c or between the terminal 25b and the terminal 25c.

The switch 25 is electrically connected, at its terminal 25c, to a terminal 5a of the switch 5. The switch 5 is electrically connected, at its terminal 5b, to a first end of the bandpass filter 8. The bandpass filter 8 is electrically connected, at its second end, to the terminal 1j. The switch 5 is electrically connected, at its terminal Sc, to a first end of the bandpass filter 9. The bandpass filter 9 is electrically connected, at its second end, to the terminal 1k.

The switch 5 electrically connects selectively between the terminal 5a and the terminal 5b or between the terminal 5a and the terminal Sc.

In the case where the switch 25 electrically connects between the terminal 25a and the terminal 25c and where the switch 5 electrically connects between the terminal 5a and the terminal 5b, the low-noise amplifier 23 amplifies a signal, which has been received at the antenna ANT3 and which has been band-passed by the bandpass filter 8, and outputs the UWB receive signal UWB_RX0 to the terminal 1c.

In the case where the switch 25 electrically connects between the terminal 25a and the terminal 25c and where the switch 5 electrically connects between the terminal 5a and the terminal 5c, the low-noise amplifier 23 amplifies a signal, which has been received at the antenna ANT4 and which has been band-passed by the bandpass filter 9, and outputs the UWB receive signal UWB_RX0 to the terminal 1c.

In the case where the switch 25 electrically connects between the terminal 25b and the terminal 25c and where the switch 5 electrically connects between the terminal 5a and the terminal 5b, the power amplifier 24 amplifies the UWB transmit signal UWB_TX for output to the antenna ANT3 through the bandpass filter 8.

In the case where the switch 25 electrically connects between the terminal 25b and the terminal 25c and where the switch 5 electrically connects between the terminal 5a and the terminal 5c, the power amplifier 24 amplifies the UWB transmit signal UWB_TX for output to the antenna ANT4 through the bandpass filter 9.

The UHB circuit 4 includes the power amplifier 31, a low-noise amplifier 32, a low-noise amplifier 33, bandpass filters 34 to 36, and a switch 37.

The power amplifier 31 is electrically connected, at its input terminal, to the terminal 1e. The power amplifier 31 is electrically connected, at its output terminal, to a first end of the bandpass filter 34. The bandpass filter 34 is electrically connected, at its second end, to a terminal 37a of the switch 37.

The low-noise amplifier 32 is electrically connected, at its output terminal, to the terminal 1f. The low-noise amplifier 32 is electrically connected, at its input terminal, to a first end of the bandpass filter 35. The bandpass filter 35 is electrically connected, at its second end, to a terminal 37b of the switch 37.

The low-noise amplifier 33 is electrically connected, at its output terminal, to the terminal 1g. The low-noise amplifier 33 is electrically connected, at its input terminal, to a first end of the bandpass filter 36. The bandpass filter 36 is electrically connected, at its second end, to a terminal 37c of the switch 37.

The switch 37 electrically connects one-to-one between the terminals 37a to 37c and the terminals 37d to 37f selectively. In the example in FIG. 1, the switch 37 electrically connects one-to-one between the terminal 37a and the terminal 37d, electrically connects one-to-one between the terminal 37b and the terminal 37e, and electrically connects one-to-one between the terminal 37c and the terminal 37f. However, this is merely a connection example. The switch 37 may electrically connect one-to-one between the terminal 37a and the terminal 37e, or may electrically connect one-to-one between the terminal 37a and the terminal 37f. The switch 37 may electrically connect one-to-one between the terminal 37b and the terminal 37d, or may electrically connect one-to-one between the terminal 37d and the terminal 37f. The switch 37 may electrically connect one-to-one between the terminal 37c and the terminal 37d, or may electrically connect one-to-one between the terminal 37d and the terminal 37e.

The case, which is illustrated in FIG. 1 and in which the switch 37 electrically connects one-to-one between the terminal 37a and the terminal 37d, electrically connects one-to-one between the terminal 37b and the terminal 37e, and electrically connects one-to-one between the terminal 37c and the terminal 37f, will be described. The power amplifier 31 amplifies the UHB transmit signal UHB_TX for output to the antenna ANT5 through the bandpass filter 34, the terminal 37a, the terminal 37d, and the bandpass filter 10. The low-noise amplifier 32 amplifies a signal, which has been received at the antenna ANT6 and which has passed through the bandpass filter 11, the terminal 37d, the terminal 37b, and the bandpass filter 35, and outputs the UHB receive signal UHB_RX0 to the terminal 1f. The low-noise amplifier 33 amplifies a signal, which has been received at the antenna ANT7 and which has passed through the bandpass filter 12, the terminal 37f, the terminal 37c, and the bandpass filter 36, and outputs the UHB receive signal UHB_RX1 to the terminal 1g.

### Issues of the First Comparison Example

The radio frequency module 100, in which the UWB circuit 3, the UHB circuit 4, the switch 5, and the bandpass filters 6 to 12 are mounted on/in the substrate 2, has a large number of devices. Therefore, the radio frequency module 100 is large in size and high in cost. In addition, the radio frequency module 100, which is large in size, has a narrower range of choices of layout for a communication device.

### A First Configuration Example of the First Embodiment

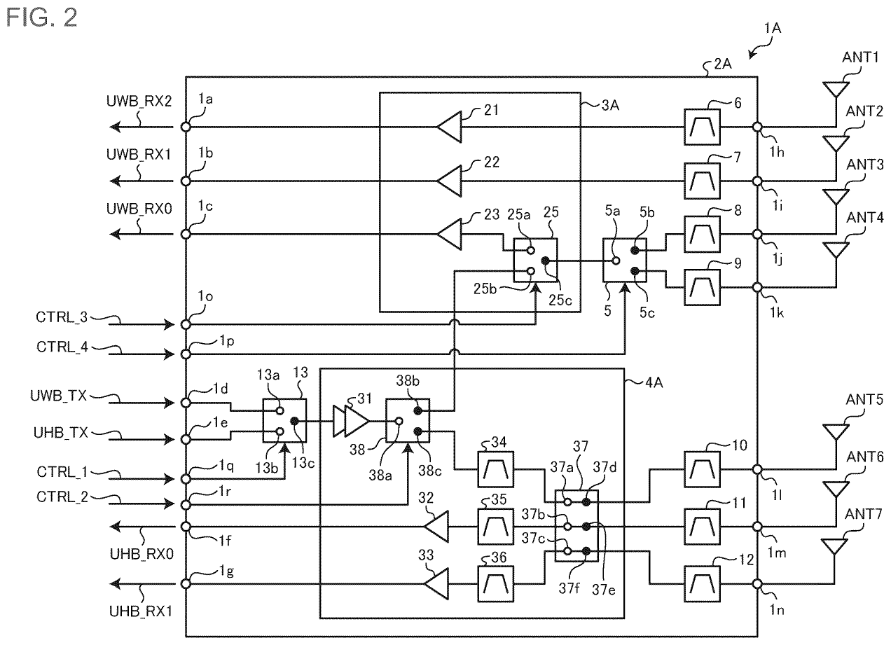

FIG. 2 is a diagram illustrating the configuration of a radio frequency module of a first configuration example of the first embodiment.

Compared with the radio frequency module 100 (see FIG. 1), a radio frequency module 1A includes a substrate 2A instead of the substrate 2. Compared with the radio frequency module 100, the radio frequency module 1A includes a UWB circuit 3A and a UHB circuit 4A instead of the UWB circuit 3 and the UHB circuit 4. Compared with the radio frequency module 100, the radio frequency module 1A further includes a switch 13.

The switch 13 may be included in the UHB circuit 4A.

The switch 5 and the bandpass filters 6 to 9 may be included in the UWB circuit 3A. The bandpass filters 10 to 12 may be included in the UHB circuit 4A.

Compared with the substrate 2, the substrate 2A further includes terminals 1o to 1r.

Compared with the UWB circuit 3, the UWB circuit 3A does not include the power amplifier 24.

Compared with the UHB circuit 4, the UHB circuit 4A further includes a switch 38.

The UWB circuit 3A corresponds to an exemplary “first semiconductor device” of the present disclosure. The UHB circuit 4A corresponds to an exemplary “second semiconductor device” of the present disclosure. The switch 13 corresponds to an exemplary “first switch” of the present disclosure. The power amplifier 31 corresponds to an exemplary “power amplifier” of the present disclosure. The switch 38 corresponds to an exemplary “second switch” of the present disclosure. The bandpass filter 8 or 9 corresponds to an exemplary “first bandpass filter” of the present disclosure. The bandpass filter 34 or 10 corresponds to an exemplary “second bandpass filter” of the present disclosure.

A control signal CTRL_3 is inputted to the terminal 1o. A control signal CTRL_4 is inputted to the terminal 1p. A control signal CTRL_1 is inputted to the terminal 1q. A control signal CTRL_2 is inputted to the terminal 1r.

The switch 13 is electrically connected, at its terminal 13a, to the terminal 1d. The switch 13 is electrically connected, at its terminal 13b, to the terminal 1e. The switch 13 is electrically connected, at its terminal 13c, to the input terminal of the power amplifier 31. The power amplifier 31 is electrically connected, at its output terminal, to a terminal 38a of the switch 38. The switch 38 is electrically connected, at its terminal 38b, to the terminal 25b of the switch 25. The switch 38 is electrically connected, at its terminal 38c, to the first end of the bandpass filter 34.

The switch 13 electrically connects selectively between the terminal 13a and the terminal 13c or between the terminal 13b and the terminal 13c in accordance with the control signal CTRL_1. The switch 38 electrically connects selectively between the terminal 38a and the terminal 38b or between the terminal 38a and the terminal 38c in accordance with the control signal CTRL_2. The switch 25 electrically connects selectively between the terminal 25a and the terminal 25c or between the terminal 25b and the terminal 25c in accordance with the control signal CTRL_3. The switch 5 electrically connects selectively between the terminal 5a and the terminal 5b or between the terminal 5a and the terminal Sc in accordance with the control signal CTRL_4.

Operations of the radio frequency module 1A that are common to those of the radio frequency module 100 will not be described.

### Operations in Amplifying the UWB Transmit Signal UWB_TX

The switch 13 electrically connects between the terminal 13a and the terminal 13c in accordance with the control signal CTRL_1. The switch 38 electrically connects between the terminal 38a and the terminal 38b in accordance with the control signal CTRL_2. The switch 25 electrically connects between the terminal 25b and the terminal 25c in accordance with the control signal CTRL_3. The switch 5 electrically connects between the terminal 5a and the terminal 5b or between the terminal 5a and the terminal Sc in accordance with the control signal CTRL_4.

The power amplifier 31 receives, at its input terminal, the UWB transmit signal UWB_TX through the terminal 1d, the terminal 13a, and the terminal 13c. The power amplifier 31 amplifies the UWB transmit signal UWB_TX for output to the antenna ANT3 through the terminal 38a, the terminal 38b, the terminal 25b, the terminal 25c, the terminal 5a, the terminal 5b, the bandpass filter 8, and the terminal 1j. Alternatively, the power amplifier 31 amplifies the UWB transmit signal UWB_TX for output to the antenna ANT4 through the terminal 38a, the terminal 38b, the terminal 25b, the terminal 25c, the terminal 5a, the terminal 5c, the bandpass filter 9, and the terminal 1k.

### Operations in Amplifying the UWB Receive Signal UWB_RX0

The switch 5 electrically connects between the terminal 5b and the terminal 5a or between the terminal Sc and the terminal 5a in accordance with the control signal CTRL_4. The switch 25 electrically connects between the terminal 25c and the terminal 25a in accordance with the control signal CTRL_3.

The low-noise amplifier 23 receives, at its input terminal, the UWB receive signal UWB_RX0 from the antenna ANT3 through the terminal 1j, the bandpass filter 8, the terminal 5b, the terminal 5a, the terminal 25c, and the terminal 25a. Alternatively, the low-noise amplifier 23 receives, at its input terminal, the UWB receive signal UWB_RX0 from the antenna ANT4 through the terminal 1k, the bandpass filter 9, the terminal 5c, the terminal 5a, the terminal 25c, and the terminal 25a. The low-noise amplifier 23 amplifies the UWB receive signal UWB_RX0 for output to the terminal 1c.

### Operations in Amplifying the UHB Transmit Signal UHB_TX

The switch 13 electrically connects between the terminal 13b and the terminal 13c in accordance with the control signal CTRL_1. The switch 38 electrically connects between the terminal 38a and the terminal 38c in accordance with the control signal CTRL_2. The switch 37 electrically connects between the terminal 37a and the terminal 37d.

The power amplifier 31 receives, at its input terminal, the UHB transmit signal UHB_TX through the terminal 1e, the terminal 13b, and the terminal 13c. The power amplifier 31 amplifies the UHB transmit signal UHB_TX for output to the antenna ANT5 through the terminal 38a, the terminal 38c, the bandpass filter 34, the terminal 37a, the terminal 37d, the bandpass filter 10, and the terminal 1l.

### Exclusive Operations in Amplifying the UWB Transmit Signal UWB_TX and the UHB Transmit Signal UHB_TX

As described above, the power amplifier 31 receives, at its input terminal, the UWB transmit signal UWB_TX or the UHB transmit signal UHB_TX in accordance with the control signal CTRL_1. That is, the power amplifier 31 amplifies the UWB transmit signal UWB_TX and the UHB transmit signal UHB_TX exclusively.

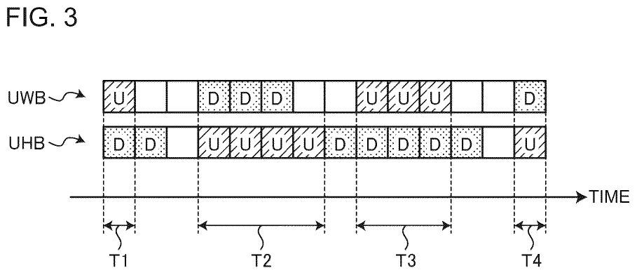

FIG. 3 is a timing chart of an operational timing example of the first embodiment and the second embodiment. In FIG. 3, “U” indicates transmission (Uplink); “D” indicates reception (Downlink).

In periods T1 and T3, the power amplifier 31 amplifies the UWB transmit signal UWB_TX, and the radio frequency module 1A transmits UWB radio waves. In periods T1 and T3, the power amplifier 31 does not amplify the UHB transmit signal UHB_TX. The radio frequency module 1A does not transmit UHB radio waves, and performs UHB reception or stops reception/transmission of UHB radio waves.

In periods T2 and T4, the power amplifier 31 amplifies the UHB transmit signal UHB_TX, and the radio frequency module 1A transmits UHB radio waves. In periods T2 and T4, the power amplifier 31 does not amplify the UWB transmit signal UWB_TX. The radio frequency module 1A does not transmit UWB radio waves, and receives UWB radio waves or stops UWB reception/transmission.

### Effect of the First Configuration Example of the First Embodiment

[1] The power amplifier 31 may be used to amplify the UWB transmit signal UWB_TX and also to amplify the UHB transmit signal UHB_TX. Thus, compared with the UWB circuit 3, the UWB circuit 3A may exclude the power amplifier 24 (see FIG. 1), allowing a reduction in size.

Therefore, compared with the radio frequency module 100, the radio frequency module 1A may be reduced in size and cost. In addition, the radio frequency module 1A, which may be reduced in size, achieves a wider range of choices of layout for a communication device.

[2] The power amplifier 31 amplifies the UWB transmit signal UWB_TX and the UHB transmit signal UHB_TX exclusively. Therefore, compared with the case in which the UWB transmit signal UWB_TX and the UHB transmit signal UHB_TX are amplified at the same time, the radio frequency module 1A achieves a reduction of the amount of heat generation.

Compared with the case in which the UWB transmit signal UHB_TX and the UHB transmit signal UHB_TX are amplified at the same time, the power amplifier 31 achieves suppression of quality degradation (distortion) of output signals. Therefore, the radio frequency module 1A achieves suppression of quality degradation of transmitted radio waves.

### APPENDIX

The radio frequency module 1A may have a matching circuit for impedance matching which is disposed on at least one of the following paths: the path from the terminal 1d to the switch 13; the path from the terminal 1e to the switch 13; the path from the switch 13 to the power amplifier 31; the path from the power amplifier 31 to the terminal 1j; the path from the power amplifier 31 to the terminal 1k; and the path from the power amplifier 31 to the terminal 1l.

### A Second Configuration Example of the First Embodiment

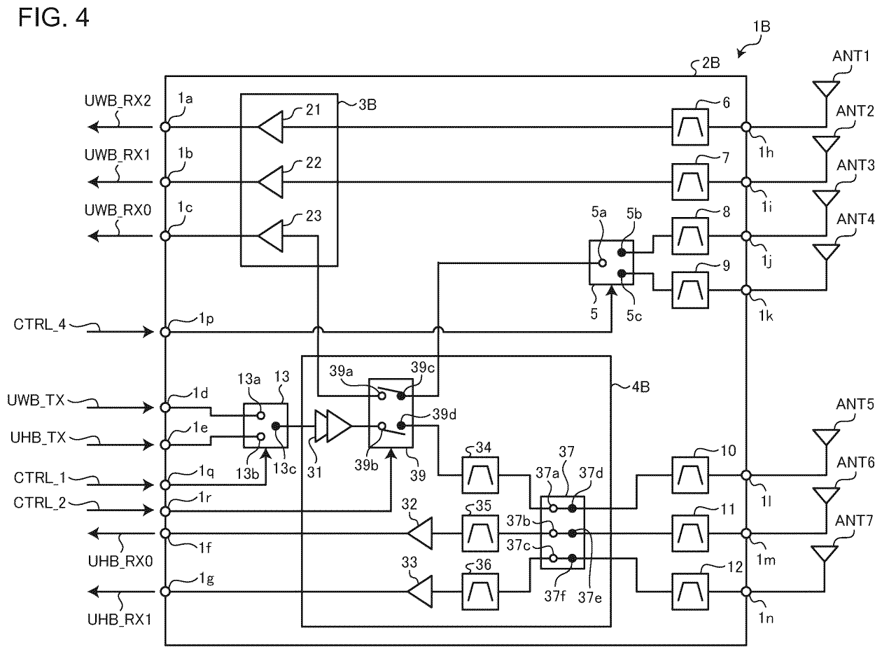

FIG. 4 is a diagram illustrating the configuration of a radio frequency module of a second configuration example of the first embodiment.

Compared with the radio frequency module 1A (see FIG. 2), a radio frequency module 1B includes a substrate 2B instead of the substrate 2A. Compared with the radio frequency module 1A, the radio frequency module 1B includes a UWB circuit 3B and a UHB circuit 4B instead of the UWB circuit 3A and the UHB circuit 4A.

The switch 13 may be included in the UHB circuit 4B.

The switch 5 and the bandpass filters 6 to 9 may be included in the UWB circuit 3B. The bandpass filters 10 to 12 may be included in the UHB circuit 4B.

Compared with the substrate 2A, the substrate 2B does not include the terminal 1o.

Compared with the UWB circuit 3A, the UWB circuit 3B does not include the switch 25.

Compared with the UHB circuit 4A, the UHB circuit 4B includes a switch 39 instead of the switch 38.

The UWB circuit 3B corresponds to an exemplary “first semiconductor device” of the present disclosure. The UHB circuit 4B corresponds to an exemplary “second semiconductor device” of the present disclosure. The switch 39 corresponds to an exemplary “second switch” of the present disclosure.

The switch 39 is electrically connected, at its terminal 39a, to the input terminal of the low-noise amplifier 23. The switch 39 is electrically connected, at its terminal 39b, to the output terminal of the power amplifier 31. The switch 39 is electrically connected, at its terminal 39c, to the terminal 5a of the switch 5. The switch 39 is electrically connected, at its terminal 39d, to the first end of the bandpass filter 34.

The switch 39 electrically connects one-to-one between the terminals 39a and 39b and the terminals 39c and 39d selectively in accordance with the control signal CTRL_2. In the example in FIG. 4, the switch 39 electrically connects one-to-one between the terminal 39a and the terminal 39c, and electrically connects one-to-one between the terminal 39b and the terminal 39d. However, this is merely a connection example. For example, the switch 39 may electrically connect one-to-one between the terminal 39b and the terminal 39c.

Operations of the radio frequency module 1B that are common to those of the radio frequency module 100 and the radio frequency module 1A will not be described.

### Operations in Amplifying the UWB Transmit Signal UWB_TX

The switch 13 electrically connects between the terminal 13a and the terminal 13c in accordance with the control signal CTRL_1. The switch 39 electrically connects between the terminal 39b and the terminal 39c in accordance with the control signal CTRL_2. The switch 5 electrically connects between the terminal 5a and the terminal 5b or between the terminal 5a and the terminal Sc in accordance with the control signal CTRL_4.

The power amplifier 31 receives, at its input terminal, the UWB transmit signal UWB_TX through the terminal 1d, the terminal 13a, and the terminal 13c. The power amplifier 31 amplifies the UWB transmit signal UWB_TX for output to the antenna ANT3 through the terminal 39b, the terminal 39c, the terminal 5a, the terminal 5b, the bandpass filter 8, and the terminal 1j. Alternatively, the power amplifier 31 amplifies the UWB transmit signal UWB_TX for output to the antenna ANT4 through the terminal 39b, the terminal 39c, the terminal 5a, the terminal 5c, the bandpass filter 9, and the terminal 1k.

### Operations in Amplifying the UWB Receive Signal UWB_RX0

The switch 5 electrically connects between the terminal 5b and the terminal 5a or between the terminal 5c and the terminal 5a in accordance with the control signal CTRL_4. The switch 39 electrically connects between the terminal 39c and the terminal 39a in accordance with the control signal CTRL_2.

The low-noise amplifier 23 receives, at its input terminal, the UWB receive signal UWB_RX0 from the antenna ANT3 through the terminal 1j, the bandpass filter 8, the terminal 5b, the terminal 5a, the terminal 39c, and the terminal 39a. Alternatively, the low-noise amplifier 23 receives, at its input terminal, the UWB receive signal UWB_RX0 from the antenna ANT4 through the terminal 1k, the bandpass filter 9, the terminal 5c, the terminal 5a, the terminal 39c, and the terminal 39a. The low-noise amplifier 23 amplifies the UWB receive signal UWB_RX0 for output to the terminal 1c.

### Operations in Amplifying the UHB Transmit Signal UHB_TX

The switch 13 electrically connects between the terminal 13b and the terminal 13c in accordance with the control signal CTRL_1. The switch 39 electrically connects between the terminal 39b and the terminal 39d in accordance with the control signal CTRL_2. The switch 37 electrically connects between the terminal 37a and the terminal 37d.

The power amplifier 31 receives, at its input terminal, the UHB transmit signal UHB_TX through the terminal 1e, the terminal 13b, and the terminal 13c. The power amplifier 31 amplifies the UHB transmit signal UHB_TX for output to the antenna ANT5 through the terminal 39b, the terminal 39d, the bandpass filter 34, the terminal 37a, the terminal 37d, the bandpass filter 10, and the terminal 1l.

### Exclusive Operations in Amplifying the UWB Transmit Signal UWB_TX and the UHB Transmit Signal UHB_TX

As described above, the power amplifier 31 receives, at its input terminal, the UWB transmit signal UWB_TX or the UHB transmit signal UHB_TX in accordance with the control signal CTRL_1. That is, the power amplifier 31 amplifies the UWB transmit signal UWB_TX and the UHB transmit signal UHB_TX exclusively. The operational timing of the radio frequency module 1B is substantially the same as that in FIG. 3, which is described above, and will be neither illustrated nor described.

### Effect of the Second Configuration Example of the First Embodiment

[1] The power amplifier 31 may be used to amplify the UWB transmit signal UWB_TX and also to amplify the UHB transmit signal UHB_TX. Thus, like the UWB circuit 3A, compared with the UWB circuit 3, the UWB circuit 3B may exclude the power amplifier 24 (see FIG. 1), allowing a reduction in size.

Compared with the UWB circuit 3A, the UWB circuit 3B may exclude the switch 25 (see FIG. 2), allowing a further reduction in size.

Therefore, compared with the radio frequency module 1A, the radio frequency module 1B may be further reduced in size and cost. The radio frequency module 1B, which may be further reduced in size, achieves a much wider range of choices of layout for a communication device.

[2] The power amplifier 31 amplifies the UWB transmit signal UWB_TX and the UHB transmit signal UHB_TX exclusively. Therefore, like the radio frequency module 1A, compared with the case in which the UWB transmit signal UWB_TX and the UHB transmit signal UHB_TX are amplified at the same time, the radio frequency module 1B achieves a reduction of the amount of heat generation.

Compared with the case in which the UWB transmit signal UHB_TX and the UHB transmit signal UHB_TX are amplified at the same time, the power amplifier 31 achieves suppression of quality degradation (distortion) of output signals. Therefore, like the radio frequency module 1A, the radio frequency module 1B achieves suppression of quality degradation of transmitted radio waves.

### APPENDIX

The radio frequency module 1B may have a matching circuit for impedance matching which is disposed on at least one of the following paths: the path from the terminal 1d to the switch 13; the path from the terminal 1e to the switch 13; the path from the switch 13 to the power amplifier 31; the path from the power amplifier 31 to the terminal 1j; the path from the power amplifier 31 to the terminal 1k; and the path from the power amplifier 31 to the terminal 1l.

### A Third Configuration Example of the First Embodiment

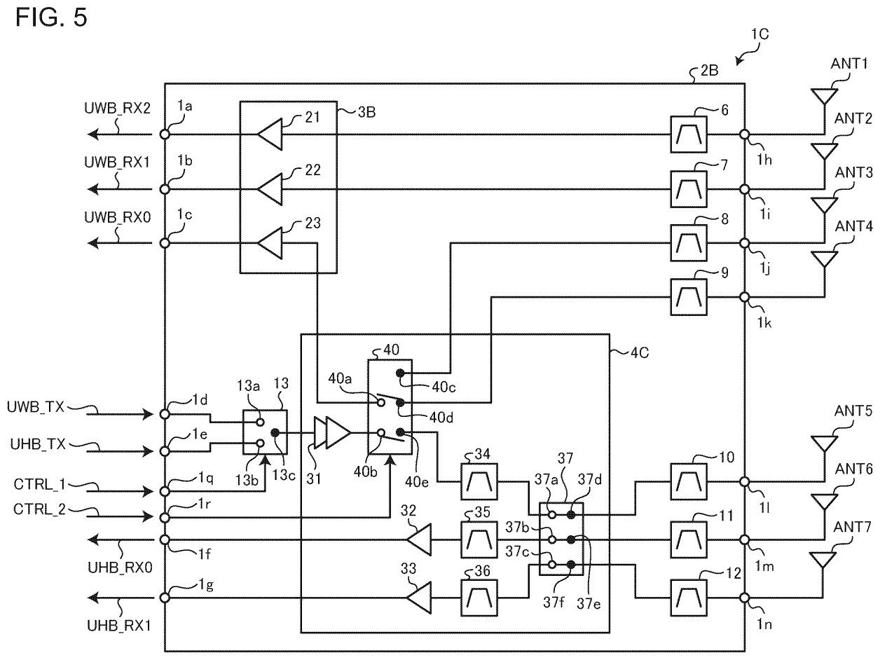

FIG. 5 is a diagram illustrating the configuration of a radio frequency module of a third configuration example of the first embodiment.

Compared with the radio frequency module 1B (see FIG. 4), a radio frequency module 1C includes a UHB circuit 4C instead of the UHB circuit 4B.

The switch 13 may be included in the UHB circuit 4C.

The bandpass filters 10 to 12 may be included in the UHB circuit 4C.

Compared with the UHB circuit 4B, the UHB circuit 4C includes a switch 40 instead of the switch 39.

The UHB circuit 4C corresponds to an exemplary “second semiconductor device” of the present disclosure. The switch 40 corresponds to an exemplary “second switch” of the present disclosure.

The switch 40 is electrically connected, at its terminal 40a, to the input terminal of the low-noise amplifier 23. The switch 40 is electrically connected, at its terminal 40b, to the output terminal of the power amplifier 31. The switch 40 is electrically connected, at its terminal 40c, to the first end of the bandpass filter 8. The switch 40 is electrically connected, at its terminal 40d, to the first end of the bandpass filter 9. The switch 40 is electrically connected, at its terminal 40e, to the first end of the bandpass filter 34.

The switch 40 electrically connects one-to-one between the terminals 40a and 40b and the terminals 40c to 40e selectively in accordance with the control signal CTRL_2. In the example in FIG. 5, the switch 40 electrically connects one-to-one between the terminal 40a and the terminal 40d, and electrically connects one-to-one between the terminal 40b and the terminal 40e. However, this is merely a connection example. For example, the switch 40 may electrically connect one-to-one between the terminal 40a and the terminal 40c.

Operations of the radio frequency module 1C that are common to those of the radio frequency module 100, the radio frequency module 1A, and the radio frequency module 1B will not be described.

### Operations in Amplifying the UWB Transmit Signal UWB_TX

The switch 13 electrically connects between the terminal 13a and the terminal 13c in accordance with the control signal CTRL_1. The switch 40 electrically connects between the terminal 40b and the terminal 40c or between the terminal 40b and the terminal 40d in accordance with the control signal CTRL_2.

The power amplifier 31 receives, at its input terminal, the UWB transmit signal UWB_TX through the terminal 1d, the terminal 13a, and the terminal 13c. The power amplifier 31 amplifies the UWB transmit signal UWB_TX for output to the antenna ANT3 through the terminal 40b, the terminal 40c, the bandpass filter 8, and the terminal 1j. Alternatively, the power amplifier 31 amplifies the UWB transmit signal UWB_TX for output to the antenna ANT4 through the terminal 40b, the terminal 40d, the bandpass filter 9, and the terminal 1k.

### Operations in Amplifying the UWB Receive Signal UWB_RX0

The switch 40 electrically connects between the terminal 40c and the terminal 40a or between the terminal 40d and the terminal 40a in accordance with the control signal CTRL_2.

The low-noise amplifier 23 receives, at its input terminal, the UWB receive signal UWB_RX0 from the antenna ANT3 through the terminal 1j, the bandpass filter 8, the terminal 40c, and the terminal 40a. Alternatively, the low-noise amplifier 23 receives, at its input terminal, the UWB receive signal UWB_RX0 from the antenna ANT4 through the terminal 1k, the bandpass filter 9, the terminal 40d, and the terminal 40a. The low-noise amplifier 23 amplifies the UWB receive signal UWB_RX0 for output to the terminal 1c.

### Operations in Amplifying the UHB Transmit Signal UHB_TX

The switch 13 electrically connects between the terminal 13b and the terminal 13c in accordance with the control signal CTRL_1. The switch 40 electrically connects between the terminal 40b and the terminal 40e in accordance with the control signal CTRL_2. The switch 37 electrically connects between the terminal 37a and the terminal 37d.

The power amplifier 31 receives, at its input terminal, the UHB transmit signal UHB_TX through the terminal 1e, the terminal 13b, and the terminal 13c. The power amplifier 31 amplifies the UHB transmit signal UHB_TX for output to the antenna ANT5 through the terminal 40b, the terminal 40e, the bandpass filter 34, the terminal 37a, the terminal 37d, the bandpass filter 10, and the terminal 1l.

### Exclusive Operations in Amplifying the UWB Transmit Signal UWB_TX and the UHB Transmit Signal UHB_TX

As described above, the power amplifier 31 receives, at its input terminal, the UWB transmit signal UWB_TX or the UHB transmit signal UHB_TX in accordance with the control signal CTRL_1. That is, the power amplifier 31 amplifies the UWB transmit signal UWB_TX and the UHB transmit signal UHB_TX exclusively. The operational timing of the radio frequency module 1C is substantially the same as that in FIG. 3, which is described above, and will be neither illustrated nor described.

### Effect of the Third Configuration Example of the First Embodiment

[1] The power amplifier 31 may be used to amplify the UWB transmit signal UWB_TX and also to amplify the UHB transmit signal UHB_TX. Thus, like the UWB circuit 3A, the UWB circuit 3B may exclude the power amplifier 24 (see FIG. 1), allowing a reduction in size.

Compared with the UWB circuit 3A, the UWB circuit 3B may exclude the switch 25 (see FIG. 2), allowing a further reduction in size.

Compared with the radio frequency module 1B (see FIG. 4), the radio frequency module 1C may exclude the switch 5, allowing a further reduction in size.

Therefore, compared with the radio frequency module 1B, the radio frequency module 1C may be further reduced in size and cost. The radio frequency module 1C, which may be further reduced in size, achieves a much wider range of choices of layout for a communication device.

[2] The power amplifier 31 amplifies the UWB transmit signal UWB_TX and the UHB transmit signal UHB_TX exclusively. Therefore, like the radio frequency module 1A and the radio frequency module 1B, compared with the case in which the UWB transmit signal UWB_TX and the UHB transmit signal UHB_TX are amplified at the same time, the radio frequency module 1C achieves a reduction of the amount of heat generation.

Compared with the case in which the UWB transmit signal UHB_TX and the UHB transmit signal UHB_TX are amplified at the same time, the power amplifier 31 achieves suppression of quality degradation (distortion) of output signals. Therefore, like the radio frequency module 1A and the radio frequency module 1B, the radio frequency module 1C achieves suppression of quality degradation of transmitted radio waves.

### APPENDIX

The radio frequency module 1C may have a matching circuit for impedance matching which is disposed on at least one of the following paths: the path from the terminal 1d to the switch 13; the path from the terminal 1e to the switch 13; the path from the switch 13 to the power amplifier 31; the path from the power amplifier 31 to the terminal 1j; the path from the power amplifier 31 to the terminal 1k; and the path from the power amplifier 31 to the terminal 1l.

### A Fourth Configuration Example of the First Embodiment

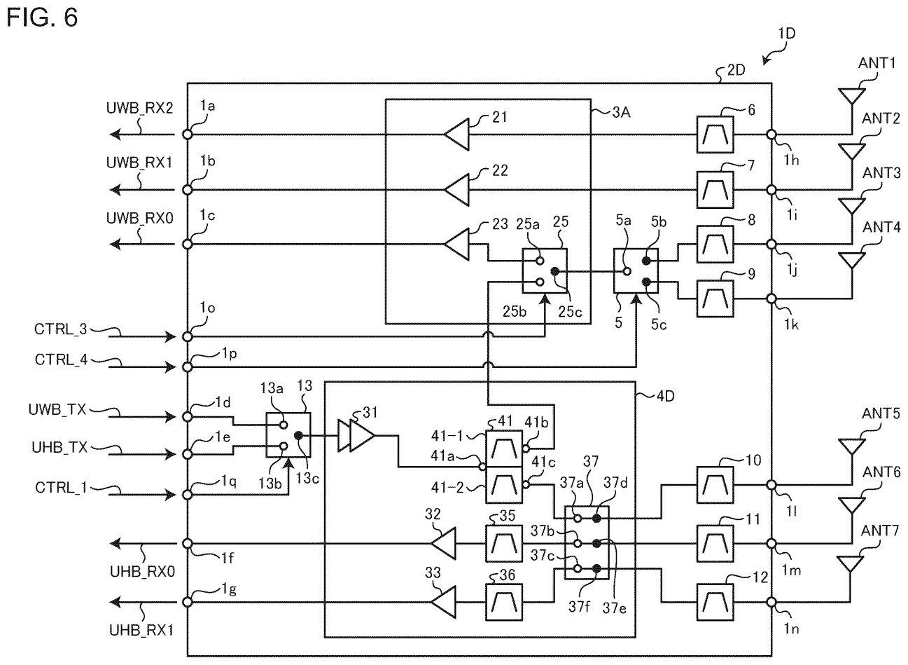

FIG. 6 is a diagram illustrating the configuration of a radio frequency module of a fourth configuration example of the first embodiment.

Compared with the radio frequency module 1A (see FIG. 2), a radio frequency module 1D includes a substrate 2D instead of the substrate 2A. Compared with the radio frequency module 1A, the radio frequency module 1D includes a UHB circuit 4D instead of the UHB circuit 4A.

The switch 13 may be included in the UHB circuit 4D.

The bandpass filters 10 to 12 may be included in the UHB circuit 4D.

Compared with the substrate 2A, the substrate 2D does not include the terminal 1r.

Compared with the UHB circuit 4A, the UHB circuit 4D includes a diplexer 41 instead of the switch 38 and the bandpass filter 34.

The UHB circuit 4D corresponds to an exemplary “second semiconductor device” of the present disclosure. The diplexer 41 corresponds to an exemplary “diplexer” of the present disclosure.

The diplexer 41 is electrically connected, at its terminal 41a, to the output terminal of the power amplifier 31. The diplexer 41 is electrically connected, at its terminal 41b, to the terminal 25b of the switch 25. The diplexer 41 is electrically connected, at its terminal 41c, to the terminal 37a of the switch 37.

The diplexer 41 has a first part 41-1 which band-passes UWB signal components of a signal, which is received at the terminal 41a, for output from the terminal 41b. The diplexer 41 has a second part 41-2 which band-passes UHB signal components of a signal, which is received at the terminal 41a, for output from the terminal 41c.

Operations of the radio frequency module 1D that are common to those of the radio frequency module 100 and the radio frequency modules 1A to 1C will not be described.

### Operations in Amplifying the UWB Transmit Signal UWB_TX

The switch 13 electrically connects between the terminal 13a and the terminal 13c in accordance with the control signal CTRL_1. The switch 25 electrically connects between the terminal 25b and the terminal 25c in accordance with the control signal CTRL_3. The switch 5 electrically connects between the terminal 5a and the terminal 5b or between the terminal 5a and the terminal Sc in accordance with the control signal CTRL_4.

The power amplifier 31 receives, at its input terminal, the UWB transmit signal UWB_TX through the terminal 1d, the terminal 13a, and the terminal 13c. The power amplifier 31 amplifies the UWB transmit signal UWB_TX for output to the antenna ANT3 through the terminal 41a, the first part 41-1 of the diplexer 41, the terminal 41b, the terminal 25b, the terminal 25c, the terminal 5a, the terminal 5b, the bandpass filter 8, and the terminal 1j. Alternatively, the power amplifier 31 amplifies the UWB transmit signal UWB_TX for output to the antenna ANT4 through the terminal 41a, the first part 41-1 of the diplexer 41, the terminal 41b, the terminal 25b, the terminal 25c, the terminal 5a, the terminal 5c, the bandpass filter 9, and the terminal 1k.

### Operations in Amplifying the UWB Receive Signal UWB_RX0

The switch 5 electrically connects between the terminal 5b and the terminal 5a or between the terminal Sc and the terminal 5a in accordance with the control signal CTRL_4. The switch 25 electrically connects between the terminal 25c and the terminal 25a in accordance with the control signal CTRL_3.

The low-noise amplifier 23 receives, at its input terminal, the UWB receive signal UWB_RX0 from the antenna ANT3 through the terminal 1j, the bandpass filter 8, the terminal 5b, the terminal 5a, the terminal 25c, and the terminal 25a. Alternatively, the low-noise amplifier 23 receives, at its input terminal, the UWB receive signal UWB_RX0 from the antenna ANT4 through the terminal 1k, the bandpass filter 9, the terminal 5c, the terminal 5a, the terminal 25c, and the terminal 25a. The low-noise amplifier 23 amplifies the UWB receive signal UWB_RX0 for output to the terminal 1c.

### Operations in Amplifying the UHB Transmit Signal UHB_TX

The switch 13 electrically connects between the terminal 13b and the terminal 13c in accordance with the control signal CTRL_1.

The power amplifier 31 receives, at its input terminal, the UHB transmit signal UHB_TX through the terminal 1e, the terminal 13b, and the terminal 13c. The power amplifier 31 amplifies the UHB transmit signal UHB_TX for output to the antenna ANT5 through the terminal 41a, the second part 41-2 of the diplexer 41, the terminal 41c, the terminal 37a, the terminal 37d, the bandpass filter 10, and the terminal 1l.

### Exclusive Operations in Amplifying the UWB Transmit Signal UWB_TX and the UHB Transmit Signal UHB_TX

As described above, the power amplifier 31 receives, at its input terminal, the UWB transmit signal UWB_TX or the UHB transmit signal UHB_TX in accordance with the control signal CTRL_1. That is, the power amplifier 31 amplifies the UWB transmit signal UWB_TX and the UHB transmit signal UHB_TX exclusively. The operational timing of the radio frequency module 1B is substantially the same as that in FIG. 3, which is described above, and will be neither illustrated nor described.

### Effect of the Fourth Configuration Example of the First Embodiment

[1] The power amplifier 31 may be used to amplify the UWB transmit signal UWB_TX and also to amplify the UHB transmit signal UHB_TX. Thus, compared with the UWB circuit 3 (see FIG. 1), the UWB circuit 3A may exclude the power amplifier 24 (see FIG. 1), allowing a reduction in size.

Therefore, like the radio frequency module 1A, compared with the radio frequency module 100, the radio frequency module 1D may be reduced in size and cost. The radio frequency module 1D, which may be reduced in size, achieves a wider range of choices of layout for a communication device.

[2] The power amplifier 31 amplifies the UWB transmit signal UWB_TX and the UHB transmit signal UHB_TX exclusively. Therefore, like the radio frequency module 1A, compared with the case in which the UWB transmit signal UWB_TX and the UHB transmit signal UHB_TX are amplified at the same time, the radio frequency module 1D achieves a reduction of the amount of heat generation.

Compared with the case in which the UWB transmit signal UHB_TX and the UHB transmit signal UHB_TX are amplified at the same time, the power amplifier 31 achieves suppression of quality degradation (distortion) of output signals. Therefore, like the radio frequency module 1A, the radio frequency module 1D achieves suppression of quality degradation of transmitted radio waves.

### APPENDIX

The radio frequency module 1D may have a matching circuit for impedance matching which is disposed on at least one of the following paths: the path from the terminal 1d to the switch 13; the path from the terminal 1e to the switch 13; the path from the switch 13 to the power amplifier 31; the path from the power amplifier 31 to the terminal 1j; the path from the power amplifier 31 to the terminal 1k; and the path from the power amplifier 31 to the terminal 1l.

### A Fifth Configuration Example of the First Embodiment

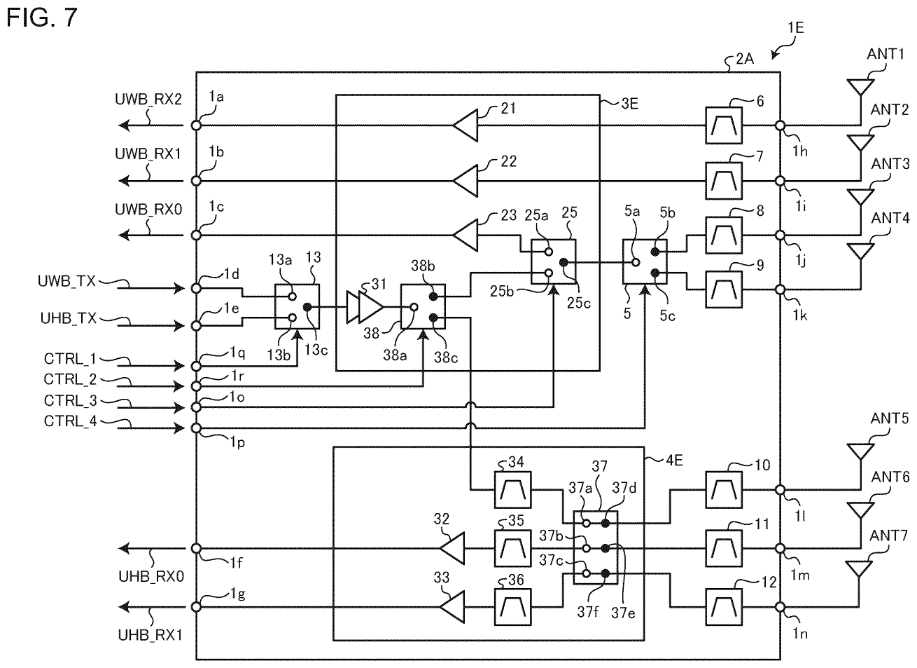

FIG. 7 is a diagram illustrating the configuration of a radio frequency module of a fifth configuration example of the first embodiment.

Compared with the radio frequency module 1A (see FIG. 2), a radio frequency module 1E includes a UWB circuit 3E and a UHB circuit 4E instead of the UWB circuit 3A and the UHB circuit 4A.

The switch 13 may be included in the UWB circuit 3E.

Compared with the UHB circuit 4A, the UHB circuit 4E does not include the power amplifier 31 and the switch 38.

Compared with the UWB circuit 3A, the UWB circuit 3E further includes the power amplifier 31 and the switch 38.

The UWB circuit 3E corresponds to an exemplary “first semiconductor device” of the present disclosure. The UHB circuit 4E corresponds to an exemplary “second semiconductor device” of the present disclosure.

The connection relationship among the switch 13, the power amplifier 31, and the switch 38 is substantially the same as that of the radio frequency module 1A, and will not be described.

The operations of the radio frequency module 1E are substantially the same as those of the radio frequency module 1A, and will not be described.

### Effect of the Fifth Configuration Example of the First Embodiment

[1] The power amplifier 31 may be used to amplify the UWB transmit signal UWB_TX and also to amplify the UHB transmit signal UHB_TX. Thus, compared with the radio frequency module 100, the radio frequency module 1E may exclude the power amplifier 24 (see FIG. 1), allowing a reduction in size.

Therefore, like the radio frequency module 1A, compared with the radio frequency module 100, the radio frequency module 1E may be reduced in size and cost. The radio frequency module 1E, which may be reduced in size, achieves a wider range of choices of layout for a communication device.

[2] The power amplifier 31 amplifies the UWB transmit signal UWB_TX and the UHB transmit signal UHB_TX exclusively. Therefore, like the radio frequency module 1A, compared with the case in which the UWB transmit signal UWB_TX and the UHB transmit signal UHB_TX are amplified at the same time, the radio frequency module 1E achieves a reduction of the amount of heat generation.

Compared with the case in which the UWB transmit signal UHB_TX and the UHB transmit signal UHB_TX are amplified at the same time, the power amplifier 31 achieves suppression of quality degradation (distortion) of output signals. Therefore, like the radio frequency module 1A, the radio frequency module 1E achieves quality degradation of transmitted radio waves.

### APPENDIX

The radio frequency module 1E may have a matching circuit for impedance matching which is disposed on at least one of the following paths: the path from the terminal 1d to the switch 13; the path from the terminal 1e to the switch 13; the path from the switch 13 to the power amplifier 31; the path from the power amplifier 31 to the terminal 1j; the path from the power amplifier 31 to the terminal 1k; and the path from the power amplifier 31 to the terminal 1l.

### A Sixth Configuration Example of the First Embodiment

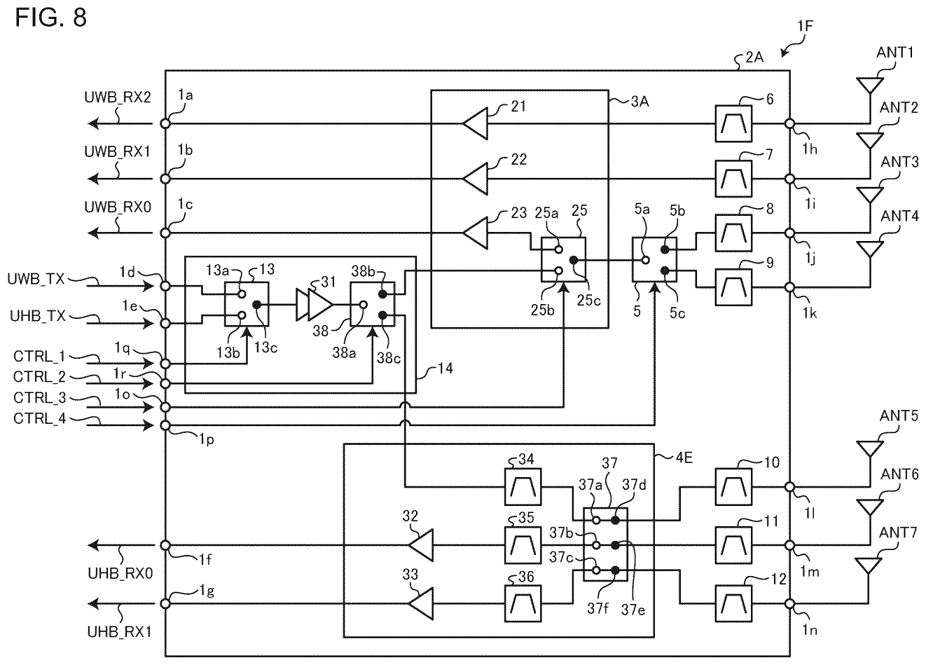

FIG. 8 is a diagram illustrating the configuration of a radio frequency module of a sixth configuration example of the first embodiment.

Compared with the radio frequency module 1A (see FIG. 2), a radio frequency module 1F includes the UHB circuit 4E instead of the UHB circuit 4A. Compared with the radio frequency module 1A, the radio frequency module 1F further includes a circuit 14.

The circuit 14 may be a single semiconductor device.

The circuit 14 corresponds to an exemplary “third semiconductor device” of the present disclosure.

The circuit 14 includes the switch 13, the power amplifier 31, and the switch 38.

The connection relationship among the switch 13, the power amplifier 31, and the switch 38 is substantially the same as that of the radio frequency module 1A, and will not be described.

The operations of the radio frequency module 1F are substantially the same as those of the radio frequency module 1A, and will not be described.

### Effect of the Sixth Configuration Example of the First Embodiment

[1] The power amplifier 31 may be used to amplify the UWB transmit signal UWB_TX and also to amplify the UHB transmit signal UHB_TX. Thus, compared with the radio frequency module 100, the radio frequency module 1F may exclude the power amplifier 24 (see FIG. 1), allowing a reduction in size.

Therefore, like the radio frequency module 1A, compared with the radio frequency module 100, the radio frequency module 1F may be reduced in size and cost. The radio frequency module 1F, which may be reduced in size, achieves a wider range of choices of layout for a communication device.

[2] The power amplifier 31 amplifies the UWB transmit signal UWB_TX and the UHB transmit signal UHB_TX exclusively. Therefore, like the radio frequency module 1A, compared with the case in which the UWB transmit signal UWB_TX and the UHB transmit signal UHB_TX are amplified at the same time, the radio frequency module 1F achieves a reduction of the amount of heat generation.

Compared with the case in which the UWB transmit signal UHB_TX and the UHB transmit signal UHB_TX are amplified at the same time, the power amplifier 31 achieves suppression of quality degradation (distortion) of output signals. Therefore, like the radio frequency module 1A, the radio frequency module 1F achieves suppression of quality degradation of transmitted radio waves.

### APPENDIX

The radio frequency module 1F may have a matching circuit for impedance matching which is disposed on at least one of the following paths: the path from the terminal 1d to the switch 13; the path from the terminal 1e to the switch 13; the path from the switch 13 to the power amplifier 31; the path from the power amplifier 31 to the terminal 1j; the path from the power amplifier 31 to the terminal 1k; and the path from the power amplifier 31 to the terminal 1l.

### Second Embodiment

To understand the second embodiment easily, prior to description about the second embodiment, a second comparison example will be described.

### The Configuration of the Second Comparison Example

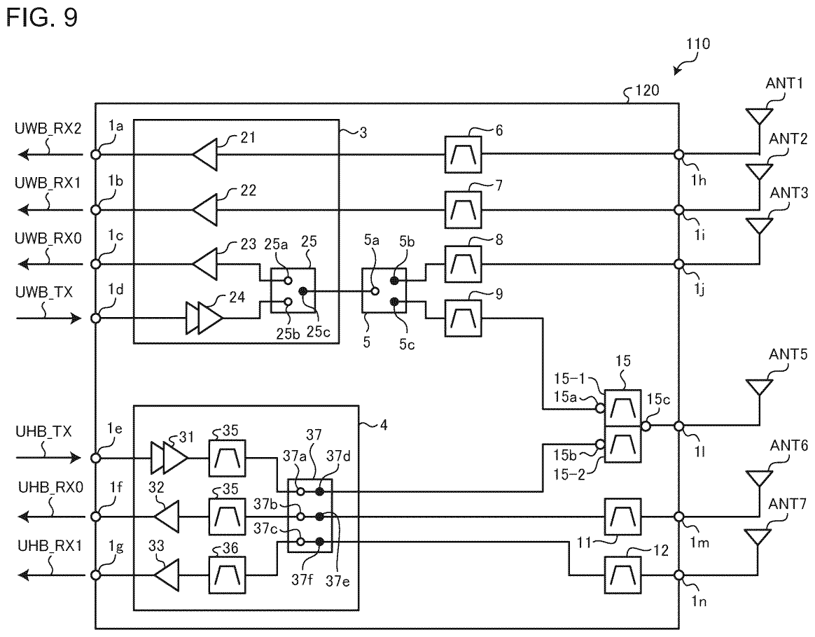

FIG. 9 is a diagram illustrating the configuration of a radio frequency module of the second comparison example.

Compared with the radio frequency module 100 (see FIG. 1), a radio frequency module 110 includes a substrate 120 instead of the substrate 2. Compared with the radio frequency module 100, the radio frequency module 110 does not include the bandpass filter 10. Compared with the radio frequency module 100, the radio frequency module 110 further includes a diplexer 15.

Compared with the substrate 2, the substrate 120 does not include the terminal 1k. Therefore, the radio frequency module 110 is not electrically connected to the antenna ANT4 (see FIG. 1).

The terminal 1l corresponds to an exemplary “fifth external connection terminal” of the present disclosure. The antenna ANT5 corresponds to an exemplary “third antenna” of the present disclosure.

In the radio frequency module 110, the antenna ANT5 is used both for reception/transmission of UWB radio waves and for reception/transmission of UHB radio waves.

The diplexer 15 is electrically connected, at its terminal 15a, to the second end of the bandpass filter 9. The diplexer 15 is electrically connected, at its terminal 15b, to the terminal 37d of the switch 37. The diplexer 15 is electrically connected, at its terminal 15c, to the terminal 1l.

The diplexer 15 has a first part 15-1 which band-passes UWB signal components of a signal, which is received at the terminal 15a, for output from the terminal 15c. The diplexer 15 has a second part 15-2 which band-passes UHB signal components of a signal, which is received at the terminal 15b, for output from the terminal 15c. The first part 15-1 of the diplexer 15 band-passes UWB signal components of a signal, which is received at the terminal 15c, for output from the terminal 15a. The second part 15-2 of the diplexer 15 band-passes UHB signal components of a signal, which is received at the terminal 15c, for output from the terminal 15b.

Operations of the radio frequency module 110 that are common to those of the radio frequency module 100 will not be described.

### Operations in Amplifying the UWB Transmit Signal UWB_TX

The switch 25 electrically connects between the terminal 25b and the terminal 25c. The switch 5 electrically connects between the terminal 5a and the terminal 5b or between the terminal 5a and the terminal 5c.

The power amplifier 24 receives, at its input terminal, the UWB transmit signal UWB_TX through the terminal 1d. The power amplifier 24 amplifies the UWB transmit signal UWB_TX for output to the antenna ANT3 through the terminal 25a, the terminal 25c, the terminal 5a, the terminal 5b, the bandpass filter 8, and the terminal 1j. Alternatively, the power amplifier 24 amplifies the UWB transmit signal UWB_TX for output to the antenna ANT5 through the terminal 25b, the terminal 25c, the terminal 5a, the terminal 5c, the bandpass filter 9, the terminal 15a, the first part 15-1 of the diplexer 15, the terminal 15c, and the terminal 1k.

### Operation in Amplifying the UWB Receive Signal UWB_RX0

The switch 5 electrically connects between the terminal 5b and the terminal 5a or between the terminal 5c and the terminal 5a. The switch 25 electrically connects between the terminal 25c and the terminal 25a.

The low-noise amplifier 23 receives, at its input terminal, the UWB receive signal UWB_RX0 from the antenna ANT3 through the terminal 1j, the bandpass filter 8, the terminal 5b, the terminal 5a, the terminal 25c, and the terminal 25a. Alternatively, the low-noise amplifier 23 receives, at its input terminal, the UWB receive signal UWB_RX0 from the antenna ANT5 through the terminal 1l, the terminal 15c, the first part 15-1 of the diplexer 15, the terminal 15a, the bandpass filter 9, the terminal Sc, the terminal 5a, the terminal 25c, and the terminal 25a. The low-noise amplifier 23 amplifies the UWB receive signal UWB_RX0 for output to the terminal 1c.

### Operations in Amplifying the UHB Transmit Signal UHB_TX

The switch 37 electrically connects between the terminal 37a and the terminal 37d.

The power amplifier 31 receives, at its input terminal, the UHB transmit signal UHB_TX through the terminal 1e. The power amplifier 31 amplifies the UHB transmit signal UHB_TX for output to the antenna ANT5 through the bandpass filter 34, the terminal 37a, the terminal 37d, the terminal 15b, the second part 15-2 of the diplexer 15, the terminal 15c, and the terminal 1l.

### Issues of the Second Comparison Example

The radio frequency module 110, in which the UWB circuit 3, the UHB circuit 4, the switch 5, the bandpass filters 6 to 9, the bandpass filter 11, the bandpass filter 12, and the diplexer 15 are mounted on/in the substrate 120, has a large number of devices. Therefore, the radio frequency module 110 is large in size and high in cost.

### A First Configuration Example of the Second Embodiment

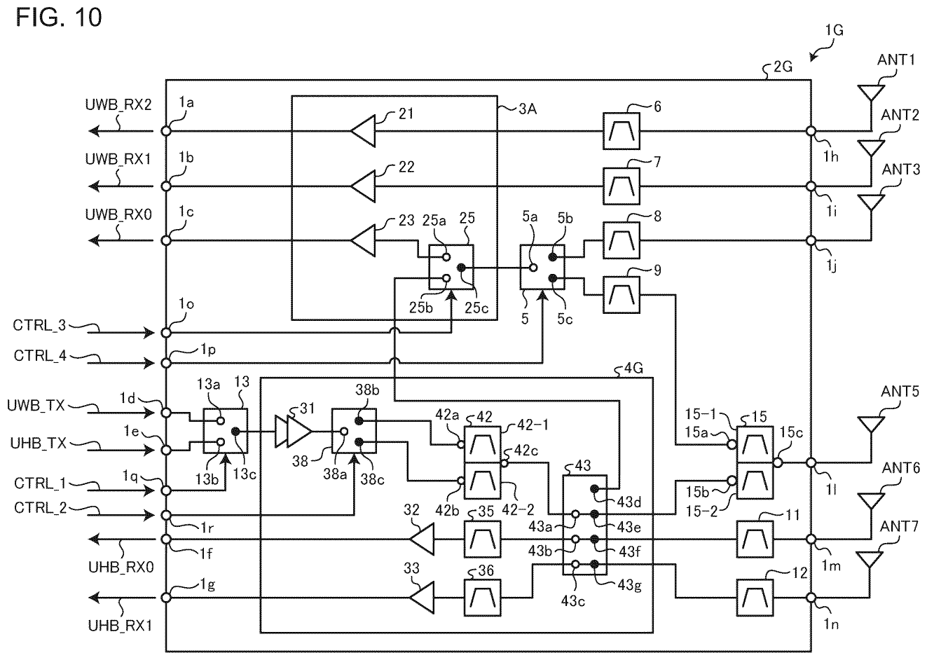

FIG. 10 is a diagram illustrating the configuration of a radio frequency module of a first configuration example of the second embodiment.

Compared with the radio frequency module 110 (see FIG. 9), a radio frequency module 1G includes a substrate 2G instead of the substrate 120. Compared with the radio frequency module 110, the radio frequency module 1G further includes the switch 13. Compared with the radio frequency module 110, the radio frequency module 1G includes the UWB circuit 3A and a UHB circuit 4G instead of the UWB circuit 3 and the UHB circuit 4.

The switch 13 may be included in the UHB circuit 4G.

Compared with the substrate 120, the substrate 2G further includes the terminals 1o to 1r.

Compared with the UHB circuit 4, the UHB circuit 4G does not include the bandpass filter 34. Compared with the UHB circuit 4, the UHB circuit 4G further includes the switch 38, a diplexer 42, and a switch 43.

The UHB circuit 4G corresponds to an exemplary “second semiconductor device” of the present disclosure. The diplexer 42 corresponds to an exemplary “diplexer” of the present disclosure.

The diplexer 42 is electrically connected, at its terminal 42a, to the terminal 38b of the switch 38. The diplexer 42 is electrically connected, at its terminal 42b, to the terminal 38c of the switch 38. The diplexer 42 is electrically connected, at its terminal 42c, to the terminal 43a of the switch 43.

The diplexer 42 has a first part 42-1 which band-passes UWB signal components of a signal, which is received at the terminal 42a, for output from the terminal 42c. The diplexer 42 has a second part 42-2 which band-passes UHB signal components of a signal, which is received at the terminal 42b, for output from the terminal 42c.

The switch 43 is electrically connected, at its terminal 43a, to the terminal 42c of the diplexer 42. The switch 43 is electrically connected, at its terminal 43b, to the second end of the bandpass filter 35. The switch 43 is electrically connected, at its terminal 43c, to the second end of the bandpass filter 36. The switch 43 is electrically connected, at its terminal 43d, to the terminal 25b of the switch 25. The switch 43 is electrically connected, at its terminal 43e, to the terminal 15b of the diplexer 15. The switch 43 is electrically connected, at its terminal 43f, to a first end of the bandpass filter 11. The switch 43 is electrically connected, at its terminal 43g, to a first end of the bandpass filter 12.

The switch 43 electrically connects one-to-one between the terminals 43a to 43c and the terminals 43d to 43g selectively. In the example in FIG. 10, the switch 43 electrically connects one-to-one between the terminal 43a and the terminal 43e, electrically connects one-to-one between the terminal 43b and the terminal 43f, and electrically connects one-to-one between the terminal 43c and the terminal 43g. However, this is merely a connection example. The switch 43 may electrically connect one-to-one between the terminal 43a and the terminal 43d, may electrically connect one-to-one between the terminal 43a and the terminal 43f, and may electrically connect one-to-one between the terminal 43a and the terminal 43g. Alternatively, the switch 43 may electrically connect one-to-one between the terminal 43b and the terminal 43e, and may electrically connect one-to-one between the terminal 43b and the terminal 43g. Alternatively, the switch 43 may electrically connect one-to-one between the terminal 43c and the terminal 43e, and may electrically connect one-to-one between the terminal 43c and the terminal 43f.

Operations of the radio frequency module 1G that are common to those of the radio frequency module 100, the radio frequency module 110, and the radio frequency modules 1A to 1F will not be described.

### Operations in Amplifying the UWB Transmit Signal UWB_TX

The switch 13 electrically connects between the terminal 13a and the terminal 13c in accordance with the control signal CTRL_1. The switch 38 electrically connects between the terminal 38a and the terminal 38b in accordance with the control signal CTRL_2. The switch 43 electrically connects between the terminal 43a and the terminal 43d. The switch 25 electrically connects between the terminal 25b and the terminal 25c in accordance with the control signal CTRL_3. The switch 5 electrically connects between the terminal 5a and the terminal 5b or between the terminal 5a and the terminal Sc in accordance with the control signal CTRL_4.

The power amplifier 31 receives, at its input terminal, the UWB transmit signal UWB_TX through the terminal 1d, the terminal 13a, and the terminal 13c. The power amplifier 31 amplifies the UWB transmit signal UWB_TX for output to the antenna ANT3 through the terminal 38a, the terminal 38b, the terminal 42a, the first part 42-1 of the diplexer 42, the terminal 42c, the terminal 43a, the terminal 43d, the terminal 25b, the terminal 25c, the terminal 5a, the terminal 5b, the bandpass filter 8, and the terminal 1j. Alternatively, the power amplifier 31 amplifies the UWB transmit signal UWB_TX for output to the antenna ANT5 through the terminal 38a, the terminal 38b, the terminal 42a, the first part 42-1 of the diplexer 42, the terminal 42c, the terminal 43a, the terminal 43d, the terminal 25b, the terminal 25c, the terminal 5a, the terminal Sc, the bandpass filter 9, the terminal 15a, the first part 15-1 of the diplexer 15, the terminal 15c, and the terminal 1l.

### Operations in Amplifying the UWB Receive Signal UWB_RX0

The switch 5 electrically connects between the terminal 5b and the terminal 5a or between the terminal 5c and the terminal 5a in accordance with the control signal CTRL_4. The switch 25 electrically connects between the terminal 25c and the terminal 25a in accordance with the control signal CTRL_3.

The low-noise amplifier 23 receives, at its input terminal, the UWB receive signal UWB_RX0 from the antenna ANT3 through the terminal 1j, the bandpass filter 8, the terminal 5b, the terminal 5a, the terminal 25c, and the terminal 25a. Alternatively, the low-noise amplifier 23 receives, at its input terminal, the UWB receive signal UWB_RX0 from the antenna ANT5 through the terminal 1l, the terminal 15c, the first part 15-1 of the diplexer 15, the terminal 15a, the bandpass filter 9, the terminal 5c, the terminal 5a, the terminal 25c, and the terminal 25a. The low-noise amplifier 23 amplifies the UWB receive signal UWB_RX0 for output to the terminal 1c.

### Operations in Amplifying the UHB Transmit Signal UHB_TX

The switch 13 electrically connects between the terminal 13b and the terminal 13c in accordance with the control signal CTRL_1. The switch 38 electrically connects between the terminal 38a and the terminal 38c in accordance with the control signal CTRL_2. The switch 43 electrically connects between the terminal 43a and the terminal 43e.

The power amplifier 31 receives, at its input terminal, the UHB transmit signal UHB_TX through the terminal 1e, the terminal 13b, and the terminal 13c. The power amplifier 31 amplifies the UHB transmit signal UHB_TX for output to the antenna ANT5 through the terminal 38a, the terminal 38c, the terminal 42b, the second part 42-2 of the diplexer 42, the terminal 42c, the terminal 43a, the terminal 43e, the terminal 15b, the second part 15-2 of the diplexer 15, the terminal 15c, and the terminal 1l.

### Exclusive Operations in Amplifying the UWB Transmit Signal UWB_TX and the UHB Transmit Signal UHB_TX

As described above, the power amplifier 31 receives, at its input terminal, the UWB transmit signal UWB_TX or the UHB transmit signal UHB_TX in accordance with the control signal CTRL_1. That is, the power amplifier 31 amplifies the UWB transmit signal UWB_TX and the UHB transmit signal UHB_TX exclusively. The operational timing of the radio frequency module 1G is substantially the same as that in FIG. 3, which is described above, and will be neither illustrated nor described.

### Effect of the First Configuration Example of the Second Embodiment

[1] The power amplifier 31 may be used to amplify the UWB transmit signal UWB_TX and also to amplify the UHB transmit signal UHB_TX. Thus, compared with the UWB circuit 3, the UWB circuit 3A may exclude the power amplifier 24 (see FIG. 9), allowing a reduction in size.

Therefore, compared with the radio frequency module 110, the radio frequency module 1G may be reduced in size and cost. The radio frequency module 1G, which may be reduced in size, achieves a wider range of choices of layout for a communication device.

[2] The power amplifier 31 amplifies the UWB transmit signal UWB_TX and the UHB transmit signal UHB_TX exclusively. Therefore, compared with the case in which the UWB transmit signal UWB_TX and the UHB transmit signal UHB_TX are amplified at the same time, the radio frequency module 1G achieves a reduction of the amount of heat generation.

Compared with the case in which the UWB transmit signal UHB_TX and the UHB transmit signal UHB_TX are amplified at the same time, the power amplifier 31 achieves suppression of quality degradation (distortion) of output signals. Therefore, the radio frequency module 1G achieves suppression of quality degradation of transmitted radio waves.

### APPENDIX

[1] The radio frequency module 1G may have a matching circuit for impedance matching which is disposed on the path from the power amplifier 31 to the terminal 1j, the path from the power amplifier 31 to the terminal 1l, or at least one of the following paths: the path from the terminal 1d to the switch 13; the path from the terminal 1e to the switch 13; and the path from the switch 13 to the power amplifier 31.

[2] The first configuration example of the second embodiment may be combined with the fifth configuration example of the first embodiment. That is, the power amplifier 31 and the switch 38 may be included in the UWB circuit 3A instead of the UHB circuit 4G.

The first configuration example of the second embodiment may be combined with the sixth configuration example of the first embodiment. That is, the switch 13, the power amplifier 31, and the switch 38 may be included in a third semiconductor device instead of the UHB circuit 4G.

### A Second Configuration Example of the Second Embodiment

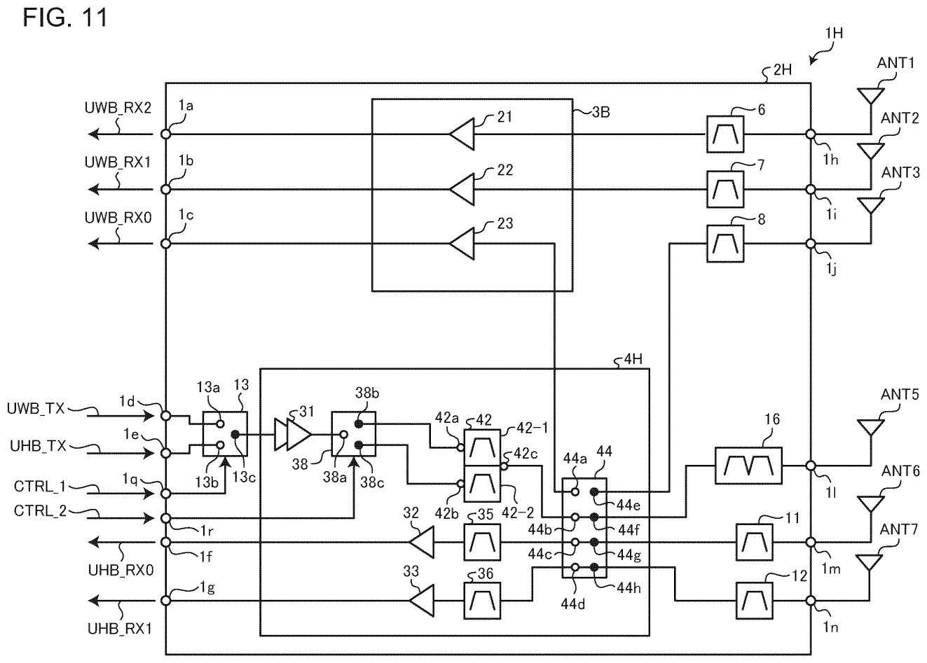

FIG. 11 is a diagram illustrating the configuration of a radio frequency module of a second configuration example of the second embodiment.

Compared with the radio frequency module 1G (see FIG. 10), a radio frequency module 1H includes a substrate 2H instead of the substrate 2G. Compared with the radio frequency module 1G, the radio frequency module 1H does not include the switch 5, the bandpass filter 9, and the diplexer 15. Compared with the radio frequency module 1G, the radio frequency module 1H includes the UWB circuit 3B and a UHB circuit 4H instead of the UWB circuit 3A and the UHB circuit 4G. Compared with the radio frequency module 1G, the radio frequency module 1H further includes a bandpass filter 16.

The switch 13 may be included in the UHB circuit 4H.

Compared with the substrate 2G, the substrate 2H does not include the terminal 1o and the terminal 1p.

The bandpass filter 16 has two passbands of the UWB signal band and the UHB signal band.

Compared with the UHB circuit 4G, the UHB circuit 4H includes a switch 44 instead of the switch 43.

The UHB circuit 4H corresponds to an exemplary “second semiconductor device” of the present disclosure.

The switch 44 is electrically connected, at its terminal 44a, to the input terminal of the low-noise amplifier 23. The switch 44 is electrically connected, at its terminal 44b, to the terminal 42c of the diplexer 42. The switch 44 is electrically connected, at its terminal 44c, to the second end of the bandpass filter 35. The switch 44 is electrically connected, at its terminal 44d, to the second end of the bandpass filter 36. The switch 44 is electrically connected, at its terminal 44e, to the first end of the bandpass filter 8. The switch 44 is electrically connected, at its terminal 44f, to a first end of the bandpass filter 16. The switch 44 is electrically connected, at its terminal 44g, to the first end of the bandpass filter 11. The switch 44 is electrically connected, at its terminal 44h, to the first end of the bandpass filter 12.

The bandpass filter 16 is electrically connected, at its second end, to the terminal 1l.

The switch 44 electrically connects one-to-one between the terminals 44a to 44d and the terminals 44e to 44h selectively. In the example in FIG. 11, the switch 44 electrically connects one-to-one between the terminal 44b and the terminal 44f, electrically connects one-to-one between the terminal 44c and the terminal 44g, and electrically connects one-to-one between the terminal 44d and the terminal 44h. However, this is merely a connection example.

Operations of the radio frequency module 1H that are common to those of the radio frequency module 100, the radio frequency module 110, and the radio frequency modules 1A to 1G will not be described.

### Operations in Amplifying the UWB Transmit Signal UWB_TX

The switch 13 electrically connects between the terminal 13a and the terminal 13c in accordance with the control signal CTRL_1. The switch 38 electrically connects between the terminal 38a and the terminal 38b in accordance with the control signal CTRL_2. The switch 44 electrically connects between the terminal 44b and the terminal 44e or between the terminal 44b and the terminal 44f.

The power amplifier 31 receives, at its input terminal, the UWB transmit signal UWB_TX through the terminal 1d, the terminal 13a, and the terminal 13c. The power amplifier 31 amplifies the UWB transmit signal UWB_TX for output to the antenna ANT3 through the terminal 38a, the terminal 38b, the terminal 42a, the first part 42-1 of the diplexer 42, the terminal 42c, the terminal 44b, the terminal 44e, the bandpass filter 8, and the terminal 1j. Alternatively, the power amplifier 31 amplifies the UWB transmit signal UWB_TX for output to the antenna ANT5 through the terminal 38a, the terminal 38b, the terminal 42a, the first part 42-1 of the diplexer 42, the terminal 42c, the terminal 44b, the terminal 44f, the bandpass filter 16, and the terminal 1l.

### Operations in Amplifying the UWB Receive Signal UWB_RX0

The switch 44 electrically connects between the terminal 44e and the terminal 44a or between the terminal 44f and the terminal 44a.

The low-noise amplifier 23 receives, at its input terminal, the UWB receive signal UWB_RX0 from the antenna ANT3 through the terminal 1j, the bandpass filter 8, the terminal 44e, and the terminal 44a. Alternatively, the low-noise amplifier 23 receives, at its input terminal, the UWB receive signal UWB_RX0 from the antenna ANT5 through the terminal 1l, the bandpass filter 16, the terminal 44f, and the terminal 44a. The low-noise amplifier 23 amplifies the UWB receive signal UWB_RX0 for output to the terminal 1c.

### Operations in Amplifying the UHB Transmit Signal UHB_TX

The switch 13 electrically connects between the terminal 13b and the terminal 13c in accordance with the control signal CTRL_1. The switch 44 electrically connects between the terminal 44b and the terminal 44f.

The power amplifier 31 receives, at its input terminal, the UHB transmit signal UHB_TX through the terminal 1e, the terminal 13b, and the terminal 13c. The power amplifier 31 amplifies the UHB transmit signal UHB_TX for output to the antenna ANT5 through the terminal 38a, the terminal 38c, the terminal 42b, the second part 42-2 of the diplexer 42, the terminal 42c, the terminal 44b, the terminal 44f, the bandpass filter 16, and the terminal 1l.

### Exclusive Operations in Amplifying the UWB Transmit Signal UWB_TX and the UHB Transmit Signal UHB_TX

As described above, the power amplifier 31 receives, at its input terminal, the UWB transmit signal UWB_TX or the UHB transmit signal UHB_TX in accordance with the control signal CTRL_1. That is, the power amplifier 31 amplifies the UWB transmit signal UWB_TX and the UHB transmit signal UHB_TX exclusively. The operational timing of the radio frequency module 1G is substantially the same as that in FIG. 3, which is described above, and will be neither illustrated nor described.

### Effect of the Second Configuration Example of the Second Embodiment

[1] The power amplifier 31 may be used to amplify the UWB transmit signal UWB_TX and also to amplify the UHB transmit signal UHB_TX. Thus, like the UWB circuit 3A, compared with the UWB circuit 3, the UWB circuit 3B may exclude the power amplifier 24 (see FIG. 9), allowing a reduction in size.

Compared with the UWB circuit 3A, the UWB circuit 3B may exclude the switch 5 and the switch 25 (see FIG. 10), allowing a further reduction in size.

Therefore, compared with the radio frequency module 1G, the radio frequency module 1H may be further reduced in size and cost. The radio frequency module 1H, which may be further reduced in size, achieves a much wider range of choices of layout for a communication device.

[2] The power amplifier 31 amplifies the UWB transmit signal UWB_TX and the UHB transmit signal UHB_TX exclusively. Therefore, compared with the case in which the UWB transmit signal UWB_TX and the UHB transmit signal UHB_TX are amplified at the same time, the radio frequency module 1H achieves a reduction of the amount of heat generation.

Compared with the case in which the UWB transmit signal UHB_TX and the UHB transmit signal UHB_TX are amplified at the same time, the power amplifier 31 achieves suppression of quality degradation (distortion) of output signals. Therefore, like the radio frequency module 1G, the radio frequency module 1H achieves suppression of quality degradation of transmitted radio waves.

### APPENDIX

[1] The radio frequency module 1H may have a matching circuit for impedance matching which is disposed on at least one of the following paths: the path from the terminal 1d to the switch 13; the path from the terminal 1e to the switch 13; the path from the switch 13 to the power amplifier 31; the path from the power amplifier 31 to the terminal 1j; and the path from the power amplifier 31 to the terminal 1l.

[2] The second configuration example of the second embodiment may be combined with the fifth configuration example of the first embodiment. That is, the power amplifier 31 and the switch 38 may be included in the UWB circuit 3B instead of the UHB circuit 4H.

The second configuration example of the second embodiment may be combined with the sixth configuration example of the first embodiment. That is, the switch 13, the power amplifier 31, and the switch 38 may be included in a third semiconductor device instead of the UHB circuit 4H.

### Configuration Examples of the Present Disclosure

The present disclosure may employ the following configurations.

(1)

A radio frequency module comprising:
a first semiconductor device that includes a circuit for a signal in a first frequency band;
a second semiconductor device that includes a circuit for a signal in a second frequency band different from the first frequency band;
a first external connection terminal that receives a transmit signal in the first frequency band;
a second external connection terminal that receives a transmit signal in the second frequency band;
a first switch that is electrically connected selectively to the first external connection terminal or the second external connection terminal;
a power amplifier that receives a signal outputted from the first switch;
a third external connection terminal that receives a selectively-transported output signal from the power amplifier and that is electrically connected to an external first antenna; and
a fourth external connection terminal that receives a selectively-transported output signal from the power amplifier and that is electrically connected to an external second antenna.

(2)

A radio frequency module comprising:
a first semiconductor device that includes a circuit for a signal in a first frequency band;
a second semiconductor device that includes a circuit for a signal in a second frequency band different from the first frequency band;
a first external connection terminal that receives a transmit signal in the first frequency band;
a second external connection terminal that receives a transmit signal in the second frequency band;
a first switch that is electrically connected selectively to the first external connection terminal or the second external connection terminal;
a power amplifier that receives a signal outputted from the first switch;
a second switch that receives an output signal from the power amplifier;
a diplexer that receives a signal outputted from the second switch; and
a fifth external connection terminal that receives a signal outputted from the diplexer and that is electrically connected to an external third antenna.

(3)

The radio frequency module according to (1), further comprising:
a second switch that receives an output signal from the power amplifier;
a first bandpass filter that is disposed between the second switch and the third external connection terminal; and
a second bandpass filter that is disposed between the second switch and the fourth external connection terminal.

(4)

The radio frequency module according to (1), further comprising:
a diplexer that receives an output signal from the power amplifier,
wherein the diplexer is electrically connected to the third external connection terminal, and
wherein the diplexer is electrically connected to the fourth external connection terminal.

(5)

The radio frequency module according to any one of (1), (3), and (4), further comprising:
a matching circuit for impedance matching that is disposed on at least one of paths, the paths including a path from the first external connection terminal to the first switch, a path from the second external connection terminal to the first switch, a path from the first switch to the power amplifier, a path from the power amplifier to the third external connection terminal, and a path from the power amplifier to the fourth external connection terminal.

(6)

The radio frequency module according to (2), further comprising:
a matching circuit for impedance matching that is disposed on at least one of paths, the paths including a path from the first external connection terminal to the first switch, a path from the second external connection terminal to the first switch, a path from the first switch to the power amplifier, a path from the power amplifier to the second switch, a path from the second switch to the diplexer, and a path from the diplexer to the fifth external connection terminal.

(7)

The radio frequency module according to any one of (1) to (6),
wherein the first switch is controlled not to receive the transmit signal in the first frequency band and the transmit signal in the second frequency band at the same time.

(8)

The radio frequency module according to any one of (1) to (7),
wherein the power amplifier is included in the second semiconductor device.

(9)

The radio frequency module according to any one of (1) to (8),
wherein the power amplifier is included in the first semiconductor device.

(10)

The radio frequency module according to any one of (1) to (9),
wherein the power amplifier is included in a third semiconductor device.

(11)

The radio frequency module according to any one of (1) to (10),
wherein the first frequency band is UWB (Ultra Wide Band), and
wherein the second frequency band is UHB (Ultra High Band).

The embodiments are described above to facilitate understanding of the present disclosure, not to limit the interpretation of the present disclosure. The present disclosure may be changed/improved without necessarily departing from its gist. Such equivalents may be encompassed in the present disclosure.

What is claimed is:

1. A radio frequency module comprising:
a first semiconductor device comprising a circuit for a signal in a first frequency band;
a second semiconductor device comprising a circuit for a signal in a second frequency band, the second frequency band being different from the first frequency band;
a first external connection terminal that receives a transmit signal in the first frequency band;
a second external connection terminal that receives a transmit signal in the second frequency band;
a first switch that is selectively electrically connected to the first external connection terminal or to the second external connection terminal;
a power amplifier that receives a signal outputted from the first switch;
a third external connection terminal that receives a selectively-transported output signal from the power amplifier and that is electrically connected to an external first antenna; and
a fourth external connection terminal that receives a selectively-transported output signal from the power amplifier and that is electrically connected to an external second antenna.

2. A radio frequency module comprising:
a first semiconductor device comprising a circuit for a signal in a first frequency band;
a second semiconductor device comprising a circuit for a signal in a second frequency band, the second frequency band being different from the first frequency band;
a first external connection terminal that receives a transmit signal in the first frequency band;
a second external connection terminal that receives a transmit signal in the second frequency band;
a first switch that is selectively electrically connected to the first external connection terminal or to the second external connection terminal;
a power amplifier that receives a signal outputted from the first switch;
a second switch that receives an output signal from the power amplifier;
a diplexer that receives a signal outputted from the second switch; and
a fifth external connection terminal that receives a signal outputted from the diplexer and that is electrically connected to an external third antenna.

3. The radio frequency module according to claim 1, further comprising:
a second switch that receives an output signal from the power amplifier;
a first bandpass filter that is between the second switch and the third external connection terminal; and
a second bandpass filter that is between the second switch and the fourth external connection terminal.

4. The radio frequency module according to claim 1, further comprising:
a diplexer that receives an output signal from the power amplifier,
wherein the diplexer is electrically connected to the third external connection terminal, and
wherein the diplexer is electrically connected to the fourth external connection terminal.

5. The radio frequency module according to claim 1, further comprising:
an impedance matching circuit that is in a first path that connects the first external connection terminal to the first switch, a second path that connects the second external connection terminal to the first switch, a third path that connects the first switch to the power amplifier, a fourth path that connects the power amplifier to the third external connection terminal, or a fifth path that connects the power amplifier to the fourth external connection terminal.

6. The radio frequency module according to claim 2, further comprising:
an impedance matching circuit that is in a first path that connects the first external connection terminal to the first switch, a second path that connects the second external connection terminal to the first switch, a third path that connects the first switch to the power amplifier, a fourth path that connects the power amplifier to the second switch, a fifth path that connects the second switch to the diplexer, or a sixth path that connects the diplexer to the fifth external connection terminal.

7. The radio frequency module according to claim 1, wherein the first switch is configured to not receive the transmit signal in the first frequency band and the transmit signal in the second frequency band at the same time.

8. The radio frequency module according to claim 2, wherein the first switch is configured to not receive the transmit signal in the first frequency band and the transmit signal in the second frequency band at the same time.

9. The radio frequency module according to claim 1, wherein the power amplifier is in the second semiconductor device.

10. The radio frequency module according to claim 2, wherein the power amplifier is in the second semiconductor device.

11. The radio frequency module according to claim 1, wherein the power amplifier is in the first semiconductor device.

12. The radio frequency module according to claim 2, wherein the power amplifier is in the first semiconductor device.

13. The radio frequency module according to claim 1, wherein the power amplifier is in a third semiconductor device.

14. The radio frequency module according to claim 2, wherein the power amplifier is in a third semiconductor device.

15. The radio frequency module according to claim 1,
wherein the first frequency band is an Ultra Wide Band (UWB) band, and
wherein the second frequency band is an Ultra High Band (UHB) band.

16. The radio frequency module according to claim 2,
wherein the first frequency band is an Ultra Wide Band (UWB) band, and
wherein the second frequency band is an Ultra High Band (UHB) band.
